(19) United States
(12) Patent Application Publication
(10) Pub. No.: US 2025/0355031 A1
(43) Pub. Date: Nov. 20, 2025

(54) HIGH VOLTAGE INTERLOCK LOOP APPARATUS, SYSTEM, AND METHODS

(71) Applicant: Consolidated Metco, Inc., Vancouver, WA (US)

(72) Inventors: Bret Hunley, Vancouver, WA (US); Venkata Sampath Sowjanya Murthy Rallapalli, Vancouver, WA (US); Nicholas M. Draayer, Happy Valley, OR (US)

(21) Appl. No.: 19/209,500

(22) Filed: May 15, 2025

Related U.S. Application Data
(60) Provisional application No. 63/648,998, filed on May 17, 2024.

(51) Int. Cl. G01R 31/00; B60R 16/023

(52) U.S. Cl. CPC G01R 31/006; B60R 16/0238

(57) ABSTRACT

In one aspect, a high voltage interlock apparatus is provided for a vehicle. The high voltage interlock apparatus includes a resistive ladder having a plurality of interfaces to connect to a plurality of high voltage interlock loop components. The resistive ladder has an input to receive electrical power for the plurality of interfaces. The resistive ladder is configured to output a signal indicative of which of the plurality of high voltage interlock components have a fault condition.

### CROSS-REFERENCE TO RELATED APPLICATION

This application claims the benefit of U.S. Provisional Application No. 63/648,998, filed May 17, 2024, which is incorporated herein by reference in its entirety.

### TECHNICAL FIELD

This disclosure relates to high voltage interlock loop systems and, more specifically, to fault detection in high voltage interlock loop systems.

### BACKGROUND

Many hybrid and electric vehicles include a high voltage interlock loop as a safety system to inhibit unintentional exposure to high-voltage power of a high voltage system of the vehicle, for example, during the assembly, repair, maintenance and operation of the vehicle. Conventional high voltage interlock loop systems include a continuous, low voltage loop that extends through the high voltage components of the vehicle, for example, through the power connectors and/or access panels of the high voltage components. The components of the high voltage interlock loop have a daisy chain wiring scheme with the components connected in series around the low voltage loop.

When a power connector is disconnected or an access panel opened, for example, the signal of the low voltage loop is interrupted indicating a potential exposure to high voltage power. Upon detecting the low voltage loop signal has been interrupted, the high voltage interlock loop system may inhibit the flow of high voltage power to the high voltage components until the low voltage loop signal is no longer interrupted. When the low voltage loop signal has been unintentionally interrupted, a technician may need to locate the source of the interruption along the low voltage loop to enable use of the high voltage system. Locating the source of the interruption can be time consuming, especially in vehicles with many high voltage components and connections.

### SUMMARY

In one aspect of the present disclosure, a high voltage interlock apparatus is provided for a vehicle. The high voltage interlock apparatus includes a resistive ladder having a plurality of interfaces to connect to a plurality of high voltage interlock loop components. The resistive ladder has an input to receive electrical power for the plurality of interfaces. The resistive ladder is configured to output a signal from an output of the resistive ladder indicative of which of the plurality of high voltage interlock components have a fault condition. In this manner, the high voltage interlock apparatus enables a determination of which of the high voltage interlock loop components has failed based upon the signal from the resistive ladder, rather than requiring a technician to manually check the high voltage interlock loop components to identify which component has failed.

In one embodiment, the resistive ladder is configured to provide a predetermined voltage of the signal to indicate which of the plurality of high voltage interlock loop components have the fault condition. For example, the resistive ladder may be configured to output a 4V signal when the high voltage interlock components are all in an operating or normal condition. In response to one of the components being in a fault condition, such as a cover of a component of the vehicle's high-voltage electrical system being removed or an electrical connector being disconnected, the resistive ladder outputs a 3.5 V signal. The changed voltage of the signal permits a processor, such as a processor of a vehicle control unit, to identify which of the high voltage interlock components is in the fault condition.

The present disclosure also provides a high voltage interlock system of a vehicle. The high voltage interlock system includes a fault detection circuit configured to be connected to a plurality of high voltage interlock loop components, the fault detection circuit configured to output a signal indicative of a fault condition of one or more of the plurality of high voltage interlock components. The high voltage interlock system further includes a vehicle control unit configured to receive the signal and determine which of the plurality of high voltage interlock loop components have the fault condition based at least in part on the signal. The fault detection circuit may be integrated with the vehicle control unit or may be a separate and distinct component connected thereto.

In another aspect of the present disclosure, a method is provided for detecting a fault condition of a high voltage interlock loop system of a vehicle having a plurality of high voltage interlock loop components connected to a fault detection circuit. The fault detection circuit is operable to output a plurality of different signals that correspond to different ones of the high voltage interlock loop components having a fault condition. The method includes outputting, from the fault detection circuit, a signal that corresponds to at least one of the high voltage interlock components having a fault condition. The method further includes determining which of the plurality of high voltage interlock loop components have a fault condition based at least in part on the signal. The method thereby facilitates a determination of which high voltage interlock component(s) of a plurality of high voltage interlock components, such as ten or more, is in a fault condition. The precise determination of the failed high voltage interlock loop component enables a technician to quickly remedy the failed component rather than having to first manually check the components of the high voltage interlock system to locate the failed high voltage interlock loop component.

### BRIEF DESCRIPTION OF THE DRAWINGS

FIG. 1 is a perspective view of a tractor-trailer having a high voltage interlock loop (HVIL) system.

FIG. 2A is a circuit diagram of the HVIL system of the trailer of FIG. 1 having a fault detection circuit to output a signal indicative of whether one or more components of the HVIL system have a fault condition.

FIG. 2B is a table of example resistance values for the resistors in the fault detection circuit of FIG. 2A.

FIG. 3 is a flow diagram of a method of detecting faults in the HVIL system of FIG. 2A.

FIG. 4 is an example table indicating which HVIL component(s) of the HVIL system of FIG. 2A have a fault condition based on a voltage of the signal output from the fault detection circuit.

FIG. 5 is an example input circuit of a vehicle control unit of the HVIL system of FIG. 2A wherein the signal of the fault detection circuit has a positive voltage.

FIG. 6 is an example input circuit of the vehicle control unit of the HVIL system of FIG. 2A wherein the signal of the fault detection circuit has a negative voltage.

FIG. 7 is a circuit diagram of a high voltage power distribution system of the trailer of FIG. 1 including power distribution circuitry to control power flow from a high voltage power source to the HVIL components.

FIG. 8 is a flow diagram of a method of disconnecting the high voltage power source from one or more HVIL components of FIG. 7 upon a detection of a fault condition.

FIG. 9 is a circuit diagram of an HVIL system according to another embodiment, the HVIL system having a fault detection circuit including multiple resistive ladders and resistive ladder signal outputs.

FIG. 10 is a table associating conditions of the HVIL system to example voltage values of a signal of the fault detection circuit of FIG. 9.

### DETAILED DESCRIPTION

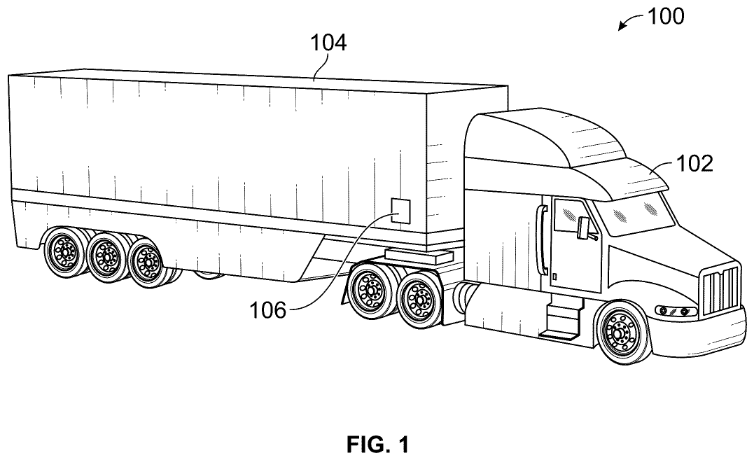

With reference to FIG. 1, a vehicle 100 is shown that includes a tractor 102 and a trailer 104. The trailer 104 has a high voltage interlock loop (HVIL) system 106. While a tractor-trailer is discussed below, those having skill in the art will readily appreciate that the disclosures herein may be applied to various vehicles such as a box truck, straight truck, cube van, locomotive, rail car, intermodal shipping container, cement mixer, mobile crane, recreational vehicle (RV), pumper or vacuum truck, mobile police or government agency command center, filmmaking support vehicle, or food truck, as some examples. Further, while the vehicle 100 is a tractor-trailer in the discussion below, it should be appreciated that the vehicle 100, in another embodiment, may be the trailer 104 independent of the tractor 102.

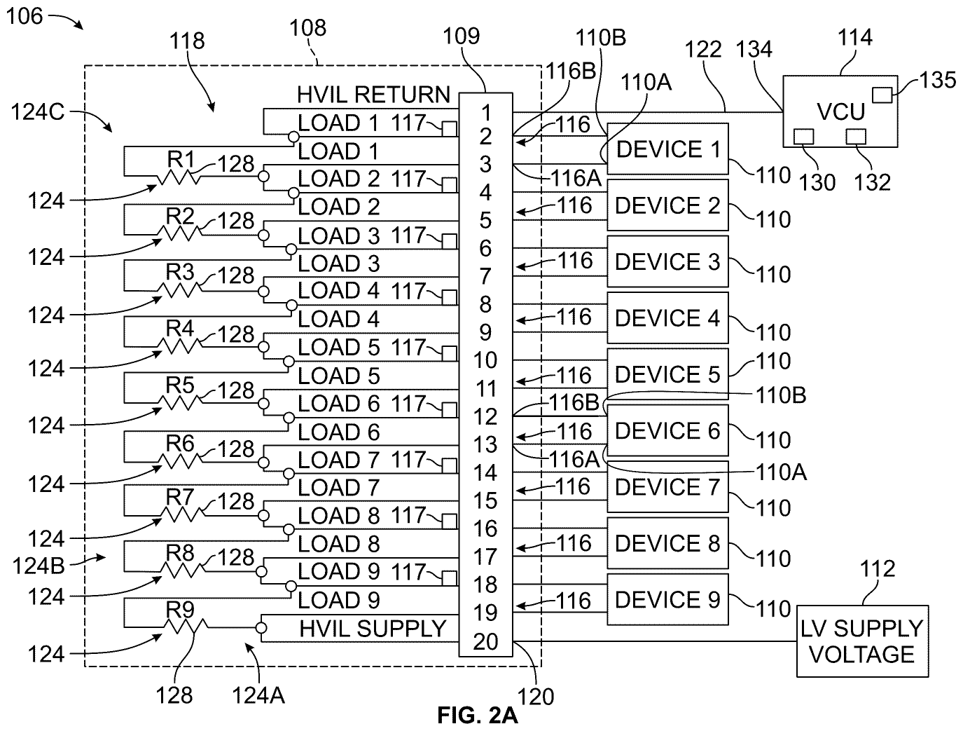

With reference to FIG. 2A, the HVIL system 106 includes a fault detection circuit 108, HVIL components 110, a low voltage power supply 112, and a vehicle control unit (VCU) 114. The HVIL components 110 may include various devices powered by a high voltage power of the vehicle 100 and/or access panels containing such a high voltage powered device. As examples, the HVIL components 110 include an emergency power cable cut location (such as an emergency E-cut on a left or right side of the vehicle), an emergency power stop button or switch (sometimes referred to as an E-stop), a high voltage power distribution circuit, a power converter, a DC-to-DC converter, an electric thermal management unit (ETMU), an electric motor, an electric generator, an electric power take-off (ePTO), an inverter, and an electrical storage device (e.g., a battery).

The fault detection circuit 108 includes a HVIL header 109 having a plurality of interfaces 116 that each may be connected to one of the HVIL components 110. The HVIL header 109 has nine interfaces 116 to connect to nine HVIL components 110 of the vehicle 100. In other embodiments, the fault detection circuit 108 may have more or fewer interfaces 116. For example, the fault detection circuit 108 may have a number of interfaces corresponding to the number of HVIL components 110 of the vehicle 100 such that each HVIL component may be connected to an interface 116 of the fault detection circuit 108. In one approach, the fault detection circuit 108 includes one or more interfaces 116 that are each connected to two or more HVIL components 110.

The HVIL header 109 provides a common component to which all of the HVIL components 110 are connected in parallel, in contrast to conventional HVIL systems where the HVIL components are connected in series or a daisy-chain configuration. The common connection point of the HVIL header 109 provides a single component at which the operation of each HVIL component 110 of the HVIL system 106 may be detected, which makes it easier to troubleshoot the HVIL system 106.

The HVIL header 109 also makes it easy to add additional HVIL components 110 to the HVIL system 106 if there are open interfaces 116 on the HVIL header 109. An open interface 116 is an interface 116 that is not connected to an HVIL component 110, although a connector may be attached to the interface 116 to close the HVIL loop when the interface 116 is not being used. The additional HVIL component 110 can be wired to the open interface 116 of the HVIL header 109 to connect the HVIL component 110 to the HVIL system 106. In some forms, the HVIL header 109 may include diagnostic circuitry, such as probe points, indicators, etc. For example, each interface 116 of the HVIL header 109, or an associated conductor of the fault detection circuit 108, may include an indicator light 117 (e.g., an LED) that indicates whether the associated HVIL component 110 has a fault. The indicator lights provide a visual indication of a fault which permits a technician inspecting the vehicle to quickly determine which HVIL component(s) 110 have a fault. The HVIL header 109 or the connectors attached to the interfaces 116 of the HVIL header 109 may include probe points to permit a technician to manually test the resistance (e.g., with a multimeter) associated with each HVIL component 110 to identify fault(s).

Each interface 116 of the fault detection circuit 108 includes an interface output 116A and an interface input 116B. The interface output 116A connects to a HVIL input 110A of the associated HVIL component 110 and the interface input 116B connects to a HVIL output 110B of the associated HVIL component 110. The fault detection circuit 108 directs a signal, such as low-voltage electricity, from the interface output 116A to the HVIL component 110. Where the HVIL component 110 has an operating or normal condition (e.g., the HVIL loop through the HVIL component 110 is uninterrupted), the interface input 116B receives the signal from the HVIL output 110B of the HVIL component 110. When a HVIL component 110 has a fault condition, such as a high voltage power connector of the HVIL component 110 is loose or disconnected and/or a high voltage access panel is open, the portion of the HVIL loop associated with the HVIL component 110 is interrupted, and the interface input 116B does not receive the signal from the HVIL output 110B.

In one embodiment, the fault detection circuit 108 includes a resistive ladder circuit 118 having the interfaces 116, a power input 120, and a resistive ladder signal output 122. The power input 120 of the resistive ladder circuit 118 receives a low voltage signal, such as at 5 volts, from the low voltage power supply 112 of the vehicle 100. The low voltage power supply 112 may be, as examples, a low voltage battery, an output of a DC-to-DC converter, or a power output of the VCU 114. The resistive ladder circuit 118 has nine stages 124 corresponding to the nine interfaces 116. Each stage 124 includes one of the interfaces 116 and a corresponding resistor 128 or another circuit component having a fixed resistance. The interface output 116A of each stage 124 receives the low voltage signal of the low voltage power supply 112 from the upstream stage 124 of the resistive ladder circuit 118. For example, the first stage 124A receives the low voltage signal from the low voltage power supply 112 and the subsequent stage 124B receive the low voltage signal from the preceding stage 124A of the resistive ladder circuit 118. The interface output 116A of the first stage 124A is connected to the power input 120 to receive the low voltage signal from the low voltage power supply 112. The interface output 116A of each subsequent stage 124 is electrically connected to the interface input 116B of the preceding stage 124 so that the low voltage signal flows sequentially through each stage 124 of the resistive ladder circuit 118. The interface input 116B of one stage 124 may be connected to the interface output 116A of the subsequent stage by a conductor, such as a wire, circuit board trace, or other low resistance conductor. The interface input 116B of the last stage 124C is electrically connected to the resistive ladder signal output 122, for example, by a low resistance conductor such as a wire or circuit board trace. The resistive ladder signal output 122 outputs a signal indicative of a normal condition with no faults or a fault condition with one or more faults.

The resistor 128 of each stage 124 connects the interface output 116A of the stage 124 to the interface input 116B of the subsequent stage 124. The flow path through the HVIL component 110 at a given stage 124 may have significantly less resistance than the flow path through the resistor 128 of the stage 124. If there is a fault condition of the HVIL component 110 associated with a given stage 124, the flow of electricity through the HVIL component 110 will be interrupted and the low voltage signal will instead travel through the resistor 128 of the stage 124. The resistor 128 thereby permits the low voltage signal to bypass the HVIL component 110 in the fault condition by flowing through the resistor 128. The resistance of the stage 124 increases when there is a fault condition in the HVIL component 110 because the low voltage power signal flows through the resistor 128 rather than the HVIL component 110. The increased resistance of the stage 124 of the resistive ladder circuit 118 causes a voltage drop in the low voltage signal across the resistor 128 and, ultimately, causes a voltage drop of the signal at the resistive ladder signal output 122. In another embodiment, one or more of the HVIL components 110 is configured to permit a reduced, but non-zero, current flow through the HVIL component 110 when the HVIL component 110 is in a fault condition.

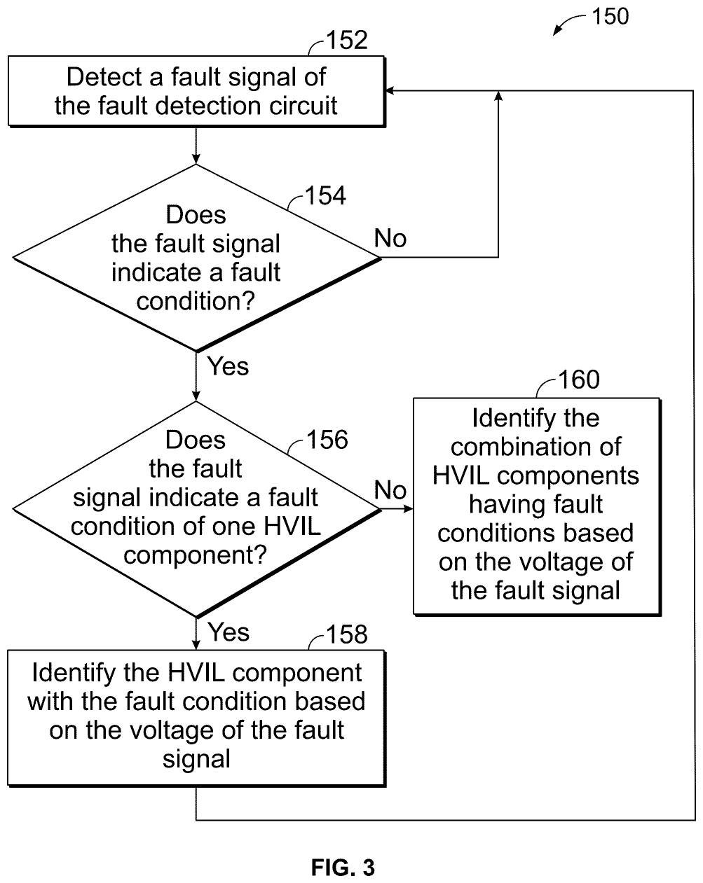

The resistor 128 of each stage 124 has a resistance selected to cause a predetermined voltage drop when the associated HVIL component 110 has a fault condition that is unique from the voltage drop associated with faults of the other HVIL components 110. Thus, when one of the HVIL components 110 has a fault condition, the VCU 114 can determine which of the HVIL components 110 has the fault condition by associating the reduced voltage of the low voltage signal at the resistive ladder signal output 122 with the one HVIL component 110 such as by using a lookup table (see, e.g., FIG. 4).

The resistors 128 may all have different resistances or, in another embodiment, two or more of the resistors 128 may have the same resistance if the resistors 128 are associated with a particular group of HVIL components 110. For example, the resistance of the resistors 128 associated with a group of HVIL components 110 including E-stop, right hand E-cut, and left hand E-cut components may be the same. When there is a fault with one of these HVIL components 110, a technician may inspect each component of the group to determine which HVIL component 110 has the fault.

The resistance value for each resistor 128 of the resistive ladder circuit 118 may be calculated so that the voltage of the resistive ladder signal output 122 indicates which individual HVIL component 110 or combination of HVIL components 110 have a fault condition. Specifically, the resistance of the resistors 128 at each stage 124 may be selected such that the resistive ladder signal has a voltage range for each fault scenario (e.g., an individual HVIL component fault or a combination of HVIL component faults) that does not overlap with the voltage ranges of the other fault scenarios such that the voltage of the resistive ladder signal output 122 indicates which fault scenario is present in the HVIL system 106. To provide non-overlapping voltage ranges for the various fault scenarios possible in the HVIL system 106, the resistance of the resistors 128 are selected so that the resistance provided by individual resistors 128 is different than the additive resistance provided by multiple resistors 128. With a resistive ladder circuit 118 of such a configuration, the voltage of the resistive ladder signal is unique upon a fault condition in any one of the HVIL components 110 or a combination of HVIL components 110 (a fault condition in two, three, or more of the HVIL components).

The example resistances in the table of FIG. 2B provide unique voltage values of the resistive ladder signal output 122 in response to any one of the HVIL components 110 being in a fault condition or any two HVIL components 110 being in a fault condition. The VCU 114 can thereby differentiate which HVIL component 110, or two HVIL components 110, are in a failure or fault condition based upon the voltage of the resistive ladder signal output 122.

Resistors R1-R3 are associated with a group of HVIL components 110 and have the same resistance of 10 KΩ. The voltage of the resistive ladder signal output 122 will be the same if any of the HVIL components 110 associated with resistors R1-R3 are in a fault condition. The VCU 114 can identify that one of the HVIL components 110 associated with the resistors R1-R3 is in a fault condition and communicate, such as via a human-machine-interface of the vehicle or a diagnostic tool connected to the VCU 114, that a service technician should check all of the HVIL components 110 associated with the resistors R1-R3 because one of the HVIL components 110 is in a fault condition. In one example, the group of HVIL components 110 includes the E-stop, right hand E-cut, and left hand E-cut components. The VCU 114 may separately monitor the states of the E-stop, right hand E-cut, and left hand E-cut via secondary integrity circuits. For example, the E-stop may be a three contact E-stop switch that has a positional sense circuit monitored by the VCU 114 to determine the position of the E-stop. Thus, upon a resistive ladder signal from the fault detection circuit 108 indicating a failure of one HVIL component 110 of the group of HVIL components 110, the VCU 114 may be able to separately determine which of the group of HVIL components 110 has failed.

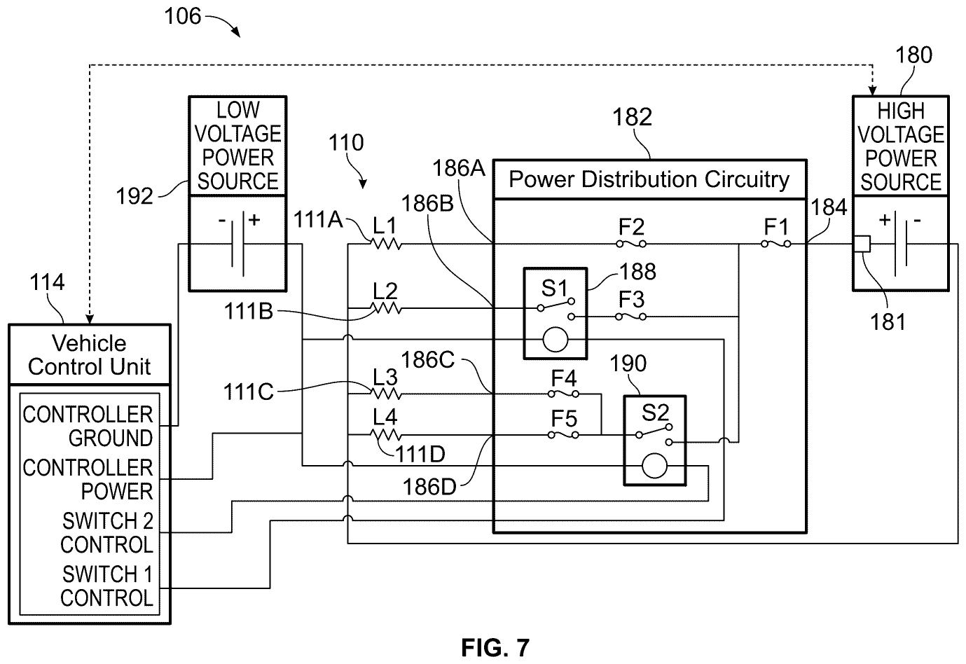

Regarding FIG. 2A, the VCU 114 has a resistive ladder signal input 134 that receives the resistive ladder signal from the resistive ladder signal output 122. The VCU 114 evaluates the resistive ladder signal to determine whether there is a fault condition and which of the HVIL components 110 have the fault condition based on the signal. The VCU 114 may constitute a main logical control unit of the HVIL system 106, meaning that the VCU 114 is responsible for logical control and management of the HVIL system 106 as well as other components of the trailer 104. The VCU 114 may include a processor 130 and memory 132. The processor 130 may execute programs and functions stored in the memory 132 to control operations of the vehicle 100 as discussed herein. The processor 130 may include, as examples, a microprocessor, an application-specific integrated circuit (ASIC), or a field programmable gate array (FPGA). The memory 132 may include, as examples, random-access memory (RAM), read-only memory (ROM), electrically erasable programmable read-only memory (EEPROM), and flash memory. The VCU 114 may include a communication interface 135 operable by the processor 130 to communicate with the other components of the vehicle 100 to send commands to and/or receive data from the components. As examples, the VCU 114 may communicate with the other components of the vehicle 100 using analog communication (e.g., discrete control wiring), serial communication (e.g., RS485), and/or a Controller Area Network (CAN bus) (e.g., J1939). The VCU 114 may, for example, communicate with a remote computing device (e.g., a computer of the tractor 102) to indicate whether a fault condition of the HVIL system 106 has been detected and/or which HVIL component(s) 110 have a fault condition. The VCU 114 may communicate an alert to notify a user when a fault condition has been detected. Regarding FIG. 7, the VCU 114 may also communicate with a high voltage power source 180 and/or a power distribution circuit 182 of the trailer 104 to inhibit flow of high voltage electrical power to some or all of the HVIL components 110 as discussed in further detail below.

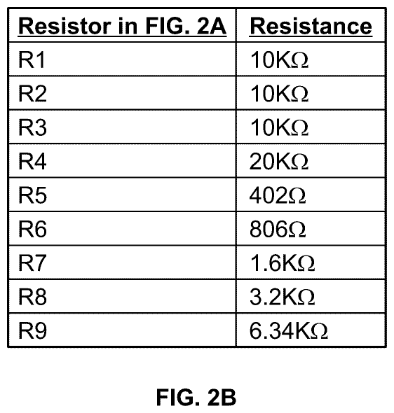

With respect to FIG. 3, the VCU 114 may utilize a method 150 to evaluate the resistive ladder signal received at the resistive ladder signal input 136 of the VCU 114. The VCU 114 detects 152 a resistive ladder signal received from the resistive ladder signal output 122 of the fault detection circuit 108. The VCU 114 may, for example, detect that the resistive ladder signal input 136 is receiving a signal from the resistive ladder signal output 122 of the fault detection circuit 108. The VCU 114 determines 154 whether the received resistive ladder signal indicates a fault condition. For example, the VCU 114 may measure a voltage of the resistive ladder signal and determine whether the measured resistive ladder signal voltage deviates from a normal resistive ladder signal voltage that indicates no faults are present. The normal resistive ladder signal voltage may depend on the voltage output by the low voltage power supply 112 and the resistance of the fault detection circuit 108 when none of the HVIL components 110 have a fault. For example, the low voltage power supply 112 may output a 5V signal but the normal resistive ladder signal voltage measured at the resistive ladder signal output 122 is 4 V. If the VCU 114 determines that the resistive ladder signal does not indicate a fault condition is present, the VCU 114 returns to step 152 to continue monitoring the resistive ladder signal until a fault condition is present.

If the VCU 114 determines a fault condition is present at step 154, the VCU determines 156 whether the resistive ladder signal indicates a fault condition of one HVIL component 110 or a combination of HVIL components 110. The VCU 114 may compare the measured voltage of the resistive ladder signal to a data structure that correlates resistive ladder signal voltage levels with fault scenarios of the HVIL system 106 (e.g., a fault condition in one or more of the HVIL components 110). The data structure that correlates resistive ladder signal voltage levels to fault conditions may be, as examples, a database, a table, and/or a formula. The data structure may be stored in the memory 132 of the VCU 114. As discussed above, the resistive ladder signal voltage levels correlate to fault scenarios of the HVIL components 110 because of the differentiated resistances of the resistors 128 of the resistive ladder circuit 118 associated with the HVIL component 110.

With respect to FIG. 4, as one example, the VCU 114 stores or is able to access a table 170 that includes voltage ranges associated with fault conditions for each HVIL component 110 and fault conditions for a combination of two of the HVIL components 110. In the table 170, the rows 172 list the HVIL components 110 of the HVIL system 106 and the columns 174 also list the HVIL components 110 of the HVIL system 106. The cells 176 where the HVIL component 110 of the row 172 is the same as the HVIL component 110 of the column indicate the voltage range associated with a fault of that individual HVIL component 110. The cells 178 where the HVIL component 110 of the row is different than the HVIL component 110 of the column indicate the voltage range associated with a fault condition in both the HVIL component 110 of the row 172 and the HVIL component 110 of the column 174. The fault conditions may be associated with a range of voltages to account for fluctuations in the low voltage signal provided by the low voltage power supply 112 to the fault detection circuit 108, resistance tolerances of the resistors 128 of the fault detection circuit 108, resistance tolerances of resistors of the VCU 114, etc. The voltage ranges associated with each fault scenario do not overlap which enables the VCU 114 to determine which HVIL component 110 or combination of HVIL components 110 have fault conditions based on the measured voltage of the resistive ladder signal.

To determine whether the resistive ladder signal indicates a fault condition of one of the HVIL components, the VCU 114 may compare the measured voltage of the resistive ladder signal detected at the resistive ladder signal output 122 to the range of voltages of the cells 176 of the table 170 indicating a fault of one of the HVIL components 110. If the measured voltage falls within one of the ranges listed in cells 176, the VCU 114 may identify 158 that the corresponding HVIL component 110 has the fault condition. For example, with reference to FIG. 4, if the measured voltage is 2.500V, the VCU 114 determines that the EHUBMOTORS component has a fault condition because 2.500V falls within the voltage range of 2.468V-2.593V associated with a fault condition in the EHUBMOTORS.

Where the resistive ladder signal does not indicate a fault condition of one HVIL component 110, the resistive ladder signal represents a fault condition of a combination of HVIL components. The VCU 114 may identify 160 the combination of HVIL components 110 having fault conditions by comparing the voltage of the resistive ladder signal detected at the resistive ladder signal output 122 to the range of voltages of the cells 178 of the table 170 that indicate fault conditions in combinations of the HVIL components 110. For example, with reference to FIG. 4, if the measured voltage is 4.000V, the VCU 114 determines that both the ETMU and the POWER CONVERTER have fault conditions because 4.000V falls within the voltage range of 3.904V-4.078V.

In other examples, the resistive ladder signal may similarly be used to identify that fault conditions are present in a combination of three, four, or more HVIL components 110. As in the above example, the voltage ranges associated with fault conditions in individual HVIL components 110 and combinations of HVIL components 110 is differentiated to enable identification of which HVIL component 110 or combination of HVIL components 110 has a fault condition. The voltage of the low voltage signal provided by the low voltage power supply 112 may be increased to permit additional ranges of voltages and/or a greater buffer between the ranges of voltages. As examples, the low voltage power supply 112 may output a low voltage signal of 5V, 12V, or 24V.

The HVIL system 106 is advantageous over conventional systems in that the VCU 114 is able to identify specific HVIL component(s) 110 that are in a fault condition. The VCU 114 can convey information identifying the HVIL component(s) 110 in the fault condition to a technician, such as via a display of the vehicle or a computer in communication with the VCU 114. For instance, the VCU 114 may use telematics to send fault information to a remote computer for fault tracking and/or to provide a technician with information about the fault before servicing the vehicle 100. The technician can then service the HVIL component(s) 110 in the fault condition and service or replace the HVIL component(s) 110 without having to inspect each HVIL component 110 of the HVIL system 106 to see whether it has failed as in conventional HVIL systems.

The VCU 114 may also determine whether the resistive ladder signal is within a normal range of voltages. For example, where the low voltage power supply 112 outputs a voltage of 5V, a normal range of voltages received from the output 122 of the fault detection circuit 108 may be about 0V to about 4V. Where the VCU 114 determines the resistive ladder signal is outside of the normal range of voltages, the VCU 114 may determine that the fault detection circuit 108 itself has failed, for example, the fault detection circuit 108 has a short. Upon determining the fault detection circuit 108 has failed, the VCU 114 may inhibit power flow to the HVIL components 110 because the VCU 114 is not able to detect faults in the HVIL system 106 using the fault detection circuit 108. The VCU 114 may also communicate a message, for example, via a human-machine-interface of the vehicle 100 or a remote server computer, of the failure condition and/or that the HVIL system 106 needs servicing.

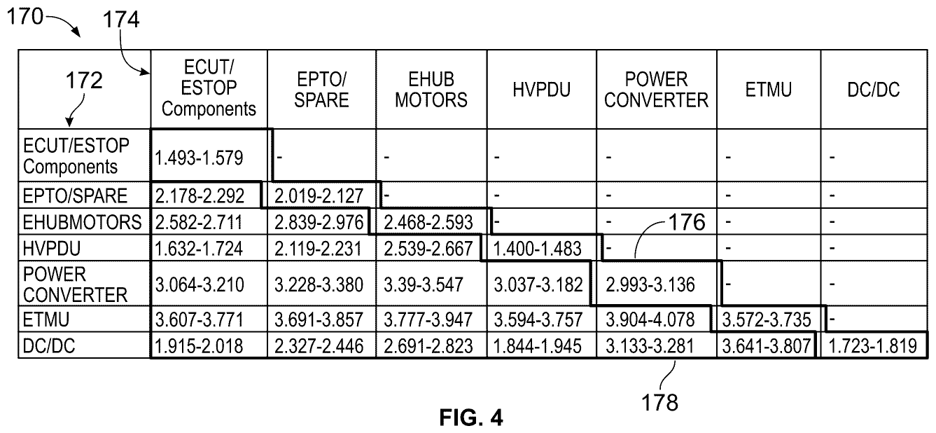

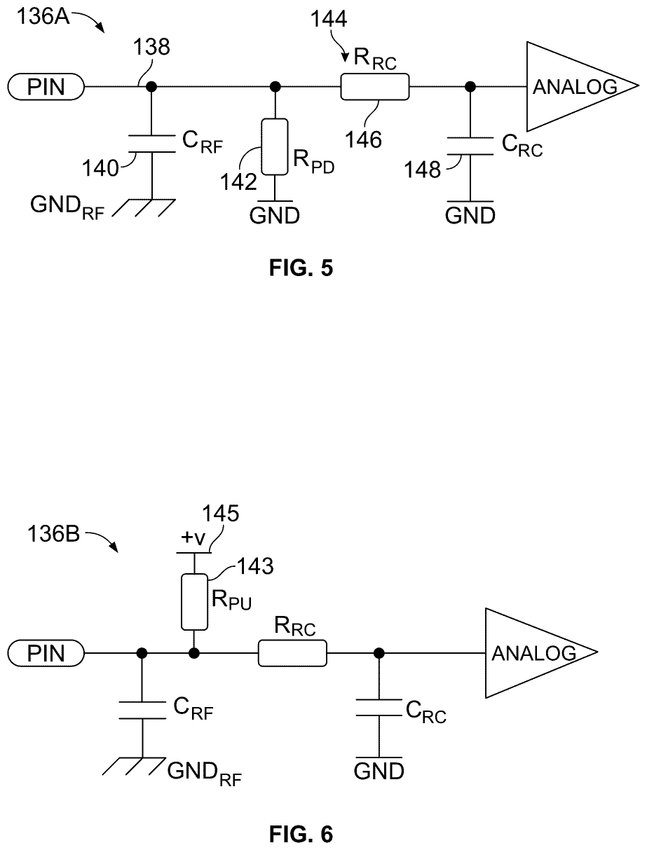

With respect to FIGS. 5 and 6, the resistive ladder signal input 136 of the VCU 114 may have different configurations based on whether the fault detection circuit 108 outputs a resistive ladder signal having a positive voltage or a negative voltage to the resistive ladder signal input 136 of the VCU 114. With reference to FIG. 5, resistive ladder signal input circuitry 136A of a first embodiment of the resistive ladder signal input 136 is provided for receiving a resistive ladder signal having a positive voltage. The resistive ladder signal input circuitry 136A has an input conductor 138 to receive the resistive ladder signal. The resistive ladder signal input circuitry 136A includes a first capacitor 140 between the input conductor 138 and ground to filter undesired frequencies from the resistive ladder signal, for example, radio frequency noise. The resistive ladder signal input circuitry 136A has a pull-down resistor 142 between the input conductor 138 and ground, for example, to ensure a 0V signal is provided to the VCU 114 when a resistive ladder signal is not being received from the fault detection circuit 108. The resistive ladder signal flows through an RC circuit 144 including a resistor 146 and a capacitor 148 to filter undesired frequencies from the resistive ladder signal received by the VCU 114 for analysis.

With reference to FIG. 6, resistive ladder signal input circuitry 136B is provided according to another embodiment of the resistive ladder signal input 136 for receiving a resistive ladder signal having a negative voltage. The resistive ladder signal input circuitry 136B may also be used where the low voltage power supply 112 is replaced with a ground connection. The resistive ladder signal input circuitry 136B is similar to the resistive ladder signal input circuitry 136A. One difference between the resistive ladder signal input circuitries 136A, 136B is that the resistive ladder signal input circuitry 136B has a pull-up resistor 143 between the input conductor 139 and a positive voltage power source 145, for example, to ensure a signal of a known voltage is provided to the VCU 114 when a resistive ladder signal is not being received from the fault detection circuit 108.

Regarding FIG. 7, in some embodiments, the HVIL system 106 may include power distribution circuitry 182 that may be operated to electrically disconnect some or all of the HVIL components 110 from the high voltage power source 180. Upon identifying which HVIL component(s) 110 have a fault condition, the VCU 114 may cause the power distribution circuitry 182 to isolate the HVIL component(s) 110 associated with the fault, for example, by electrically disconnecting the high voltage power source 180 from the HVIL component(s) 110 having the fault condition. As only the HVIL component(s) 110 associated with a fault condition are isolated, the HVIL system 106 permits high voltage power to flow to other HVIL components 110 that do not have a fault condition. The HVIL system 106 is thereby able to ensure safety by inhibiting power flow to HVIL component(s) 110 associated with a fault condition while still permitting other HVIL components 110 to function. This provides an advantage over conventional HVIL systems where all HVIL components are disconnected from high voltage power when a fault is detected rendering all of the high voltage components inoperable until the fault condition is addressed.

The power distribution circuitry 182 includes an input interface 184 to receive high voltage power from the high voltage power source 180. The high voltage power source 180 may include a high voltage battery of the trailer 104, for example, a 400V or 800V battery. The high voltage power source 180 may include a contactor 181 operable to permit or inhibit the flow of high voltage electrical power to the power distribution circuitry 182. The power distribution circuitry 182 has power outputs 186A, 186B, 186C, 186D that electrically connect to the HVIL components 110 to provide the high voltage electrical power to the HVIL components 110. In the example provided, the power distribution circuitry 182 has four power outputs to connect to four HVIL components 110, however, any number of HVIL components 110 can be similarly connected to the power distribution circuitry 182 for a given embodiment.

In some embodiments, the HVIL components 110 may be categorized as primary loads, secondary individual loads, or secondary grouped loads. In the example shown, HVIL component 111A is a primary load component connected to the power output 186A. The power distribution circuitry 182 connects the power output 186A (and thus the HVIL component 111A) directly to the high voltage power source 180 without a switch. The primary load components include HVIL components 110 that are critical to operation of the HVIL system 106 and/or the vehicle 100, such that disconnecting such primary load components from the high voltage electrical power would result in system failure or loss of primary system functions. Primary load components may include, for example, powertrain motors. While only one primary load component is shown by way of example, the HVIL system 106 may include additional primary load components. In another embodiment, the HVIL system 106 does not include any primary load components and the power distribution circuitry 182 does not have any power outputs connected to the high voltage power source 180 without a switch.

HVIL component 111B is a secondary individual load component connected to power output 186B. The power distribution circuitry 182 includes a switch 188 (e.g., a relay) that is operable to permit or inhibit flow of high voltage electrical power to the individual HVIL component 111B through the power output 186B. The switch 188 of the power distribution circuitry 182 permits control of power flow to the individual HVIL component 111B. Secondary individual loads may include HVIL components 110 that are significant loads that require individual control due to their operation states. Secondary individual load components may include, for example, inverters, motors, chargers, and other large capacity loads. While only one secondary individual load component (HVIL component 111B) is shown by way of example, the HVIL system 106 may include additional secondary load components connected to additional power outputs of the power distribution circuitry 182. In another embodiment, the HVIL system 106 does not include any secondary individual load components.

HVIL components 111C and 111D are secondary grouped load components connected to power outputs 186C and 186D, respectively. The power distribution circuitry 182 includes a switch 190 (e.g., a relay) that is operable to permit or inhibit flow of high voltage electrical power to both the HVIL components 111C, 111D through the power outputs 186C and 186D. In other words, when the switch 190 is open, electrical power is not able to flow to either of the HVIL components 111C, 111D from the power distribution circuitry 182 and when the switch 190 is closed, electrical power is able to flow to both of the HVIL components 111C, 111D. HVIL components 110 may be grouped together to be disconnected from the high voltage power source 180 as a group when one or more of the HVIL components 110 of the group have a fault condition. Secondary grouped load components may include, for example, auxiliary, non-system critical loads such as thermal management components, an ePTO, or other low power components of the HVIL system 106. While only one group of secondary grouped load components is shown by way of example, the HVIL system 106 may include additional groups of secondary grouped load components. The group(s) of HVIL components 110 may also include more than two HVIL components 110. In another embodiment, the HVIL system 106 does not include any secondary grouped load components.

The power distribution circuitry 182 may include a fuse F1 through which electrical power received by the input interface 184 flows. The power distribution circuitry may also include fuses F2, F3, F4, and F5 through which power flows to each individual HVIL component 110 for protecting the HVIL components 110.

The VCU 114 may be able to communicate with the high voltage power source 180 to cause the contactor 181 to open to inhibit high voltage power flow to the power distribution circuitry 182 and the HVIL components 110. The VCU 114 and a low voltage power source 192 (e.g., a battery) are electrically connected to the switch 188 and switch 190 such that the VCU 114 is able to control the state of the switches 188 and 190. In some forms, the VCU 114 is able to detect the state of the switches 188 and 190 to confirm that the switches 188 and 190 are in the states the VCU 114 has commanded the switches 188 and 190 to be in.

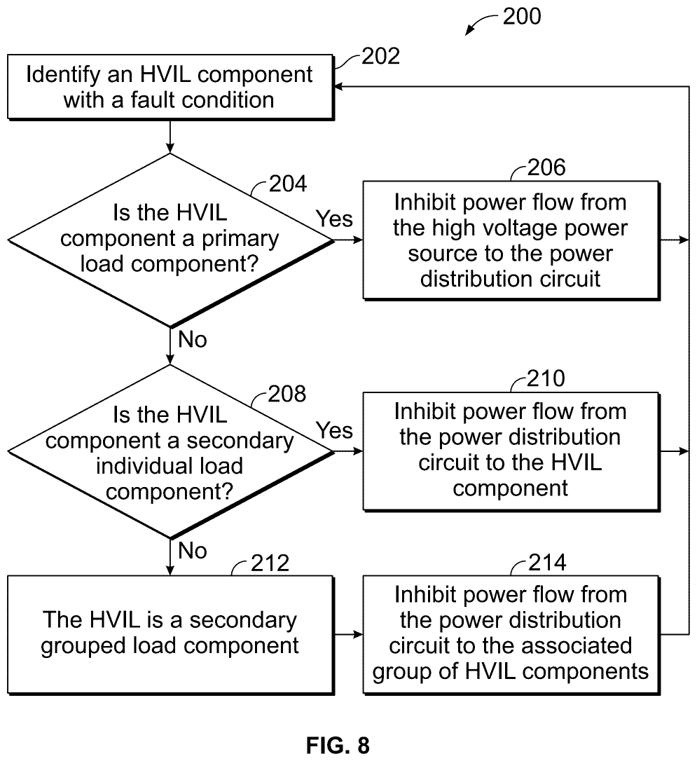

With respect to FIG. 8, the VCU 114 may perform a method 200 to disconnect the high voltage power source 180 from one or more of the HVIL components 110 upon detecting a fault condition. The VCU 114 may receive the resistive ladder signal from the fault detection circuit 108 and identify 202 which of the HVIL components have a fault condition as discussed above. The VCU 114 may determine 204 whether an identified HVIL component 110 with the fault condition is a primary load component. If the identified HVIL component 110 is a primary load component, the VCU 114 may inhibit 206 power flow from the high voltage power source 180 to the power distribution circuitry 182. Upon detecting a fault condition in a primary load component, such as HVIL component 111A, the VCU 114 communicates with the high voltage power source 180 to inhibit power flow from the high voltage power source to the power distribution circuitry 182. For example, the VCU 114 causes the contactor 181 to open to inhibit high voltage power flow to the power distribution circuitry 182. When the VCU 114 determines that the primary load component no longer has a fault condition (e.g., after being serviced), the VCU 114 may communicate with the high voltage power source 180 to permit the flow of high voltage electrical power to the power distribution circuitry 182, e.g., by causing the contactor 181 to close.

If the identified HVIL component 110 is not a primary load component, the VCU 114 may determine 208 whether the identified component is a secondary individual load component. If the identified HVIL component 110 is a secondary individual load component, the VCU 114 may inhibit 210 power flow from the power distribution circuitry 182 to the identified secondary individual load component (e.g., HVIL component 111B). For example, the VCU 114 may open the switch 188 controlling power flow to the identified secondary individual load component. The other HVIL components 110 of the HVIL system 106 that do not have a fault condition may continue to receive high voltage electrical power to operate as normal. When the VCU 114 determines that the HVIL component 111B no longer has a fault condition (e.g., after being serviced), the VCU 114 may control the switch 188 to permit the flow of high voltage electrical power to the HVIL component 111B.

In this example method 200, if the identified HVIL component is not a primary load component or a secondary individual load component, the identified HVIL component is 212 a secondary grouped load component. Upon detecting a fault condition in one or more of the secondary grouped load components, such as HVIL component 111C or 111D, the VCU 114 may inhibit 214 power flow from the power distribution circuitry 182 to the group of HVIL components 110 associated with the identified secondary grouped load component. For example, the VCU 114 may open the switch 190 that controls power flow to the group of HVIL components associated with the fault condition. When the VCU 114 determines that none of the grouped HVIL components 111C or 111D have a fault condition (e.g., when serviced), the VCU 114 may control the switch 190 to permit the flow of high voltage electrical power to the HVIL components 111C and 111D.

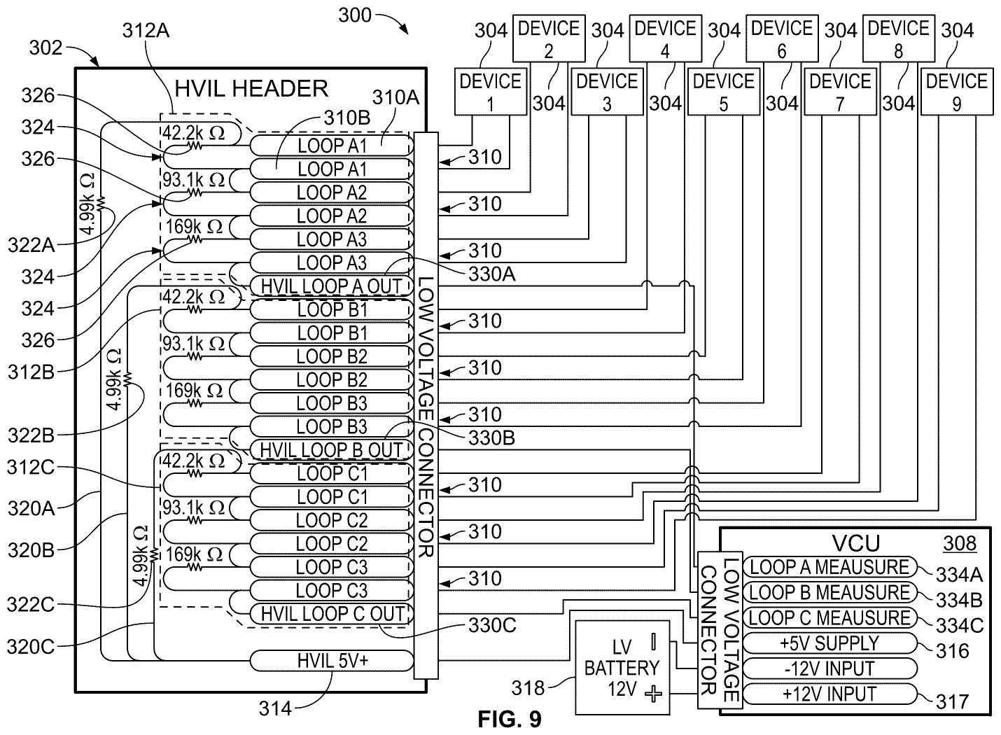

With respect to FIG. 9, a HVIL system 300 is shown that is similar in many respects to the HVIL system 106 discussed above such that the differences will be highlighted. The HVIL system 300 includes a fault detection circuit 302, HVIL components 304, and VCU 308.

The fault detection circuit 302 includes a plurality of interfaces 310 to connect to the HVIL components 304, similar to the embodiment discussed above. In the embodiment shown, the fault detection circuit 302 includes nine interfaces 310 to connect to nine HVIL components 304. One primary difference between the fault detection circuit 302 and the fault detection circuit 108 discussed above is that the fault detection circuit 302 includes multiple resistive ladder circuits 312A, 312B, 312C that each include a subset of the interfaces 310 of the fault detection circuit 320 to connect to a subset of the HVIL components 304. In the embodiment shown, the fault detection circuit 302 includes three resistive ladder circuits 312A, 312B, 312C that each include three interfaces 310 of the fault detection circuit 302 to connect to three HVIL components 304. In other embodiments, the fault detection circuit 302 may include more or fewer resistive ladder circuits 312A, 312B, 312C, for example, based on the number of HVIL components of the HVIL system 300. Additionally, in other embodiments, the number of interfaces 310 of each resistive ladder circuit 312A, 312B, 312C may be increased or decreased, for example, to provide the fault detection circuit 302 with a desired number of interfaces 310 for the HVIL components 304 of the vehicle.

The fault detection circuit 302 includes a power input 314 to receive low voltage electrical power (e.g., 5V) from a low voltage power source. The power input 314 is connected to a low voltage power output 316 of the VCU 308. The VCU 308 includes an electrical power input 317 that receives electrical power from a low voltage power source such as a low voltage battery 318 (e.g., 12V) of the vehicle with the HVIL system 300. The VCU 308 may convert the electrical power received from the low voltage battery 318 to the appropriate voltage for the fault detection circuit 302 (e.g., 5V) to be output to the fault detection circuit 302 via the low voltage power output 316. In another embodiment, the power input 314 may be connected to the low voltage battery 318.

The fault detection circuit 302 includes conductors 320A, 320B, 320C that conduct the low voltage electrical power received via the power input 314 to a respective resistive ladder circuit 312A, 312B, 312C. The conductors 320A, 320B, 320C each may include a resistor 322A, 322B, 322C through which the electrical power flows as the electrical power flows to the resistive ladder circuits 312A, 312B, 312C. The resistors 322A, 322B, 322C ensure that there is always a change in the voltage of the electrical signal sent through the resistive ladder circuits, even where there are no faults with the HVIL components 304. For example, the low voltage power output 316 of the VCU 308 may output a 5V signal to the resistive ladder circuits and when there are no faults with the HVIL components 304 of a resistive ladder circuit 312A, 312B, 312C, the resistive ladder circuit outputs a signal having a voltage of about 4.31V due to the respective resistor 322A, 322B, 322C. The voltage of the electrical signals output from the resistive ladder circuits can be monitored, for example, to detect problems in the fault detection circuit 302 (e.g., a short circuit). For instance, continuing the example above, upon detecting a 5V signal or a 0V signal output from a resistive ladder circuit, the VCU 308 may determine there is a short circuit or a broken circuit, respectively.

The resistive ladder circuits 312A, 312B, 312C may be identical in structure. For conciseness, the following discussion describes the resistive ladder circuit 312A, however, this discussion likewise applies to the resistive ladder circuits 312B and 312C. The resistive ladder circuit 312A includes three stages 324 associated with the three interfaces 310. Each stage 324 includes one of the interfaces 310 and a corresponding resistor 326 (or another circuit component having a fixed resistance). An interface output 310A of each stage 324 receives the low voltage signal of the power input 314 from the conductor 320A or the interface input 310B of the upstream stage 324 of the resistive ladder circuit 312A. In this manner, the low voltage signal flows sequentially through each stage 324 of the resistive ladder circuit 312A. The interface input 310B of the last stage 324 is electrically connected to a signal output, such as a resistive ladder signal output 330A, for example, by a low resistance conductor such as a wire or circuit board trace. The resistive ladder signal output 330A outputs a signal indicative of a normal condition with no faults or a fault condition with one or more faults.

The resistor 326 of each stage 324 connects the interface output 310A of the stage 324 to the interface input 310B of the stage 324. The flow path through the HVIL component 304 at a given stage 324 may have significantly less resistance than the flow path through the resistor 326 of the stage 324. Where no fault condition is present, the low voltage signal flows from the interface output 310A, through the HVIL component 304, and returns to the interface input 310B due to the HVIL component 304 having significantly less resistance than the resistor 326. If there is a fault condition of the HVIL component 110 associated with a given stage 324, the flow of electricity through the HVIL component 110 will be interrupted and the low voltage signal will instead travel through the resistor 326 of the stage 324. The resistor 326 thereby permits the low voltage signal to bypass the HVIL component 110 having the fault condition by flowing through the resistor 326.

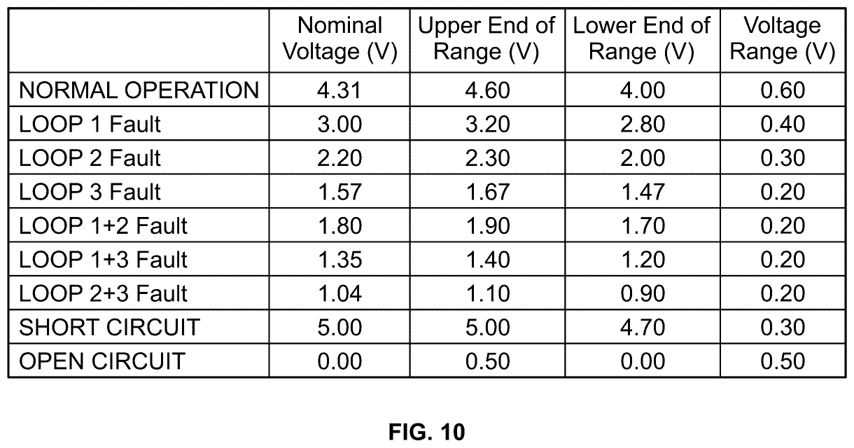

Upon flowing through each of the stages 324 of the resistive ladder circuit 312A, the electrical power flows to the resistive ladder signal output 330A of the resistive ladder circuit 312A. The resistive ladder signal output 330A is electrically connected to a resistive ladder signal input 334A of the VCU 308. The resistive ladder signal input 334A may be configured similarly to the resistive ladder signal input circuitry 136A or 136B discussed above. The VCU 308 measures the voltage of the electrical power received at the resistive ladder signal input 334A to determine whether any of the HVIL components 304 associated with the resistive ladder circuit 312A have a fault condition. The VCU 308 may also measure the voltage of the electrical power received at the signal input 334A to determine that the HVIL loop of the HVIL system has a valid configuration and is connected properly (e.g., a complete circuit without a short or break in the circuit). The resistors 326 of each stage 324 of the resistive ladder circuit 312A have a resistance selected to cause a predetermined voltage drop when the associated HVIL component 304 connected to the interface 310 of the stage 324 has a fault condition that is unique from the voltage drop associated with faults of the other HVIL components 304 of the resistive ladder circuit 312A. Thus, when one of the HVIL components 304 has a fault condition, the VCU 114 can determine which of the HVIL components 304 connected to the resistive ladder circuit 312A has the fault condition by associating the reduced voltage of the low voltage signal at the resistive ladder signal output 330A with the one HVIL component 304, for example, by using a lookup table (e.g., like the example table of FIG. 10) as discussed above.

The resistance value for each resistor 326 of the resistive ladder circuit 312A may be calculated so that the voltage of the resistive ladder signal output 330A indicates which individual HVIL component 304 or combination of HVIL components 304 have a fault condition. Specifically, the resistance of the resistors 326 at each stage 324 may be selected such that the resistive ladder signal has a voltage range for each fault scenario (e.g., an individual HVIL component fault or a combination of HVIL component faults) that does not overlap with the voltage ranges of the other fault scenarios such that the voltage of the resistive ladder signal output 330A indicates which fault scenario is present in the HVIL system 300. To provide non-overlapping voltage ranges for the various fault scenarios possible in the HVIL system 300, the resistance of the resistors 326 are selected so that the resistance provided by individual resistors 326 is different than the additive resistance provided by combinations of the resistors 326. The selection of the resistors 326 may account for the resistor tolerance and heat effects on the resistance value of the resistors 326. With a resistive ladder circuit 312A of such a configuration, the voltage of the resistive ladder signal is unique upon a fault condition in any one of the HVIL components 304 or a combination of HVIL components 304 (a fault condition in two or three of the HVIL components). By way of example, the three resistors 326 of the resistive ladder circuit 312A have the follow resistances: 42.2 KΩ; 93.1 KΩ; and 169 KΩ. However, other combinations of resistances could be used.

The resistive ladder circuits 312B and 312C likewise each include a resistive ladder signal output 330B and 330C. The resistive ladder signal outputs 330B and 330C of the resistive ladder circuits 312B and 312C may be electrically connected to resistive ladder signal inputs 334B and 334C of the VCU 308. The VCU 308 measures the voltage of the low voltage signal received at the resistive ladder signal input 334B and 334C similar to that of the resistive ladder signal input 334A to determine whether one of the HVIL components 304 or a combination thereof connected to the resistive ladder circuits 312B or 312C has a fault condition.

The VCU 308 may determine which HVIL components 304 are in fault based on the voltage of the signals received at each of the resistive ladder signal inputs 334A, 334B, 334C. For example, each HVIL component 304 of the HVIL system 300 may be associated (e.g., in a memory of the VCU 308) with one or the resistive ladder circuits 312A, 312B, 312C and a specific stage 324 or interface 310 of that resistive ladder circuit. For example, the VCU 308 may refer to a lookup table associating each stage 324 or interface 310 of the fault detection circuit 302 with one of the HVIL components 304. Upon detecting a fault from the resistive ladder signal of a resistive ladder circuit 312A, 312B, 312C, the VCU 308 may determine which HVIL component(s) 304 have a fault condition based on which stage(s) 324 of the resistive ladder circuit indicate a fault (e.g., based on the voltage of the resistive ladder signal/resistance values of the resistors 326). The VCU 308 may output an alert notifying which HVIL component 304 needs to be serviced to address the fault condition.

By including multiple resistive ladder circuits 312A, 312B, 312C, the number of stages 324 of each resistive ladder circuit may be reduced. Reducing the number of stages of the resistive ladder circuit enables a larger range of voltages to be used for each unique fault scenario. Having a larger range of voltages for each unique fault scenario reduces the voltage detection precision needed to distinguish between different fault scenarios, which may permit use of lower resolution, lower cost voltage sensor(s) used in the VCU 308. Having a larger range of voltages for each unique fault scenario also enables the use of lower grade, lower cost resistors 326 which may have higher resistance tolerances and/or have a resistance value that is more significantly affected by ambient temperature. Reducing the number of resistive ladder stages also permits voltage ranges of each unique fault scenario to be spaced apart by a buffer range of voltages that are not indicative of a fault scenario. With a larger range of voltages indicating each fault scenario and with less risk of overlap between the fault scenarios, the VCU 308 is able to more accurately determine which HVIL component or combination thereof is in fault. In other words, with fewer stages 324 in the resistive ladder circuit, the resistance of the resistors 326 may be selected to provide unique voltage ranges for each fault scenario, with each voltage range being sufficiently different to avoid overlap and inaccurate detecting of a fault scenario.

By way of example, the table of FIG. 10 associates resistive ladder signal voltages of the resistive ladder circuit 312A with a normal operation condition and fault conditions, where the resistive ladder circuit 312A receives a 5V signal and has a 42.2 KΩ, a 93.1 KΩ, and a 169 KΩ resistor 326. As shown, the normal condition and each fault condition of the HVIL components have a unique voltage range. In this example, the voltage ranges of each condition are spaced apart to ensure there is no overlap between the conditions. For example, the lower end of the voltage range of the normal condition is 4.00V and the upper end of the voltage range of the loop 1 fault is 3.20V, providing a buffer of 0.8V between the two voltage ranges. The voltage ranges for each condition also vary based on the resistance values. For instance, the lower the resistance value of the resistor (e.g., the 42.2 KΩ resistor of Loop 1), the greater the impact the resistance tolerance may have on the voltage. To account for this increased variability of the lower resistance resistors 326, a greater voltage range is provided for the lower resistance value resistors 326. A smaller voltage range may be provided for resistors 326 having a greater resistance value (e.g., the 169 KΩ resistor of Loop 3), where the resistance tolerance has less of an impact. Likewise, a smaller voltage range may be provided for conditions where multiple HVIL components have a fault condition, where the additive resistance value of the resistors 326 is higher such that the resistance tolerance has less of an impact.

Using multiple resistive ladder circuits 312A, 312B, 312C that are separately monitored by the VCU 308 enables any number of HVIL components 304 to be monitored, for example, by increasing or decreasing the number of resistive ladder circuits in the fault detection circuit 302.

While the fault detection circuit 302 includes three resistive ladder circuits 312A, 312B, 312C, in other embodiments, the HVIL system 300 may include multiple fault detection circuits 302 that each include one or more resistive ladder circuits to provide the desired number of interfaces 310 to connect to the HVIL components 304 of the vehicle. For example, to provide twelve interfaces 310, four fault detection circuits 302 may be used that each include one resistive ladder circuit 312A having three interfaces 310.

Uses of singular terms such as “a,” “an,” are intended to cover both the singular and the plural, unless otherwise indicated herein or clearly contradicted by context. The terms “comprising,” “having,” “including,” and “containing” are to be construed as open-ended terms. It is intended that the phrase “at least one of” as used herein be interpreted in the disjunctive sense. For example, the phrase “at least one of A and B” is intended to encompass A, B, or both A and B.

While there have been illustrated and described particular embodiments of the present invention, it will be appreciated that numerous changes and modifications will occur to those skilled in the art, and it is intended for the present invention to cover all those changes and modifications which fall within the scope of the appended claims.

What is claimed is:

1. A high voltage interlock apparatus of a vehicle, the high voltage interlock apparatus comprising:
a resistive ladder having a plurality of interfaces to connect to a plurality of high voltage interlock loop components;
an input of the resistive ladder to receive electrical power for the plurality of interfaces; and
an output of the resistive ladder, the resistive ladder configured to output a signal from the output indicative of which of the plurality of high voltage interlock components have a fault condition.

2. The high voltage interlock apparatus of claim 1 wherein the resistive ladder is configured to output the signal at a predetermined voltage to indicate which of the plurality of high voltage interlock loop components have the fault condition.

3. The high voltage interlock apparatus of claim 1 wherein the resistive ladder is configured to output the signal at a plurality of different voltages that correspond to different ones of the high voltage interlock components having a fault condition.

4. The high voltage interlock apparatus of claim 1 wherein the resistive ladder is configured to output the signal at a predetermined voltage in response to one of the interfaces of the plurality of interfaces not receiving a return signal from at least one of the high voltage interlock loop components.

5. The high voltage interlock apparatus of claim 1 further comprising a processor configured to:
receive the signal from the resistive ladder; and
determine which of the plurality of high voltage interlock components have a fault condition based at least in part on the signal.

6. The high voltage interlock apparatus of claim 5 wherein the processor is further configured to:
receive a second signal from a second resistive ladder having a plurality of interfaces to connect to a second plurality of high voltage interlock loop components; and
determine which of the second plurality of high voltage interlock components have a fault condition based at least in part on the second signal.

7. The high voltage interlock apparatus of claim 5 wherein the processor is further configured to detect a voltage of the signal; and
wherein to determine which of the plurality of high voltage interlock components have a fault condition includes identifying which of the plurality of high voltage interlock components have the fault condition based at least in part on a difference between the detected voltage of the signal and a normal voltage of the signal.

8. The high voltage interlock apparatus of claim 1 wherein the resistive ladder includes a plurality of resistors associated with the plurality of interfaces;
wherein, in response to one of the interfaces not receiving a return signal from at least one of the high voltage interlock loop components, the resistive ladder is configured to facilitate the flow of electric power through the resistor associated with the one interface.

9. The high voltage interlock apparatus of claim 8 wherein each resistor of the plurality of resistors has a different resistance than the other resistors of the plurality of resistors.

10. The high voltage interlock apparatus of claim 1 wherein the resistive ladder includes a plurality of resistors, each resistor of the plurality of resistors corresponding to one interface of the plurality of interfaces to electrically connect a corresponding input of the interface to a corresponding output of the interface and permit a flow of electrical power through the resistor from the corresponding output to the corresponding input in response to the corresponding interface not receiving a return signal from one of the high voltage interlock loop components associated with the one interface.

11. The high voltage interlock apparatus of claim 1 wherein the plurality of interfaces each include an interface input to be connected to a high voltage interlock loop output of at least one of the high voltage interlock loop components and an interface output to be connected to a high voltage interlock loop input of the at least one high voltage interlock loop component; and
wherein the interface output provides electrical power to the high voltage interlock loop input and the interface input receives the electrical power from the high voltage interlock loop output with the at least one the high voltage interlock loop component in a normal condition.

12. The high voltage interlock apparatus of claim 1 wherein the plurality of interfaces of the resistive ladder include:
a first interface having a first interface input and a first interface output; and
a second interface having a second interface input and a second interface output; and
wherein the second interface input is electrically connected to the first interface output to permit electrical power to flow from the first interface to the second interface.

13. The high voltage interlock apparatus of claim 1 wherein the fault condition indicates at least one of:
an exposure of a portion of a high voltage system of the vehicle; and
a high voltage interlock loop component is disconnected.

14. The high voltage interlock apparatus of claim 1, the high voltage interlock apparatus further comprising:
a second resistive ladder having a second plurality of interfaces to connect to a second plurality of high voltage interlock loop components;
a second input of the second resistive ladder to receive electrical power for the second plurality of interfaces; and
a second output of the second resistive ladder, the second resistive ladder configured to output a second signal from the second output indicative of which of the second plurality of high voltage interlock components have a fault condition.

15. A high voltage interlock system of a vehicle, the system comprising:
a fault detection circuit configured to be connected to a plurality of high voltage interlock loop components, the fault detection circuit configured to output a signal indicative of a fault condition of one or more of the plurality of high voltage interlock components; and
a vehicle control unit configured to receive the signal and determine which of the plurality of high voltage interlock loop components have the fault condition based at least in part on the signal.

16. The high voltage interlock system of claim 15 wherein to determine which of the plurality of high voltage interlock loop components have a fault condition includes determining which of the plurality of high voltage interlock loop components have the fault condition based at least in part on a voltage of the signal.

17. The high voltage interlock system of claim 15 wherein the vehicle control unit is further configured to detect a voltage of the signal; and
wherein to determine which of the plurality of high voltage interlock loop components have the fault condition includes determining one or more high voltage interlock loop components of the plurality of high voltage interlock loop components have the fault condition based at least in part on a difference between the detected voltage of the signal and a normal voltage of the signal.

18. The high voltage interlock system of claim 15 wherein, upon determining at least one high voltage interlock loop component of the plurality of high voltage interlock loop components have the fault condition, the vehicle control unit is configured to cause the at least one high voltage interlock loop component to be disconnected from high voltage electrical power.

19. The high voltage interlock system of claim 18 wherein to cause the at least one high voltage interlock loop component to be disconnected from high voltage electrical power includes causing a power distribution circuit to inhibit a flow of high voltage electrical power to the at least one high voltage interlock loop component having the fault condition.

20. The high voltage interlock system of claim 15 wherein the fault detection circuit is configured to provide a predetermined voltage of the signal to indicate which of the plurality of high voltage interlock loop components have the fault condition.

21. The high voltage interlock system of claim 15 wherein the fault detection circuit is configured to provide a predetermined voltage of the signal when the fault detection circuit does not receive a return signal from one of the high voltage interlock loop component of the plurality of high voltage interlock loop components, the predetermined signal corresponding to the one high voltage interlock loop component being in a fault condition.

22. The high voltage interlock system of claim 15 wherein the fault detection circuit includes a plurality of resistors associated with the plurality of high voltage interlock loop components; and
wherein the fault detection circuit is configured to direct electrical power through one of the resistors in response to the fault detection circuit not receiving a return signal from at least one of the high voltage interlock components associated with the one resistor.

23. The high voltage interlock system of claim 22 wherein each resistor of the plurality of resistors has a different resistance than the other resistors of the plurality of resistors.

24. The high voltage interlock system of claim 15 wherein the fault detection circuit includes a first resistive ladder circuit and a second resistive ladder circuit to be connected to the plurality high voltage interlock loop components,
wherein the signal of the fault detection circuit comprises a first signal associated with high voltage interlock loop components of the first resistive ladder and a second signal associated with high voltage interlock loop components of the second resistive ladder.

25. A method of detecting a fault condition of a high voltage interlock loop system of a vehicle having a plurality of high voltage interlock loop components connected to a fault detection circuit, the fault detection circuit operable to output a plurality of different signals that correspond to different ones of the high voltage interlock loop components having a fault condition, the method comprising:
outputting, from the fault detection circuit, a signal that corresponds to at least one of the high voltage interlock components having a fault condition; and
determining which of the plurality of high voltage interlock loop components have a fault condition based at least in part on the signal.

26. The method of claim 25 wherein outputting the fault signal includes outputting the signal with a voltage indicative of which of the plurality of high voltage interlock loop components have the fault condition.

27. The method of claim 25 wherein determining which of the plurality of high voltage interlock components have the fault condition includes identifying which of the plurality of high voltage interlock components have the fault condition based at least in part on a difference between a detected voltage of the signal and a normal signal voltage.

28. The method of claim 25 further comprising, upon determining at least one high voltage interlock loop component of the plurality of high voltage interlock loop components have the fault condition, causing the at least one high voltage interlock loop component to be disconnected from high voltage electrical power.
